(19) United States
(12) Patent Application Publication
(10) Pub. No.: US 2019/0036077 A1
(43) Pub. Date: Jan. 31, 2019

(54) METHOD FOR PRODUCING ORGANIC EL DISPLAY DEVICE, AND ORGANIC EL DISPLAY DEVICE

(71) Applicant: Sharp Kabushiki Kaisha, Sakai City, Osaka (JP)

(72) Inventors: Takeshi HIRASE, Sakai City (JP); Tetsuya OKAMOTO, Sakai City (JP); Tohru SENOO, Sakai City (JP); Tohru SONODA, Sakai City (JP); Takashi OCHI, Sakai City (JP); Mamoru ISHIDA, Sakai City (JP)

(21) Appl. No.: 16/073,814

(22) PCT Filed: Feb. 13, 2017
(86) PCT No.: PCT/JP2017/005137

§ 371 Date: Jul. 30, 2018

(30) Foreign Application Priority Data
Feb. 18, 2016 (JP) 2016-028752

(51) Int. Cl. H01L 51/52; H01L 27/32; H01L 51/00; H01L 51/56; C23C 16/40; C23C 16/455

(52) U.S. Cl. CPC H01L 51/5256; H01L 27/3244; H01L 51/0097; H01L 51/524; H01L 2251/558; C23C 16/403; C23C 16/45525; H01L 2251/5338; H01L 2251/303; H01L 51/56

(57) ABSTRACT

The present invention relates to a method including: an organic EL element formation step of forming an organic EL element (18) on an base substrate (10); and a sealing film formation step of forming a sealing film (20a) covering the organic EL element (18). The sealing film formation step includes an atomic layer deposition step of forming an inorganic barrier film (21) as the sealing film (20a) by atomic layer deposition and a molecular layer deposition step of forming an inorganic-organic composite barrier film (22) as the sealing film (20a) by molecular layer deposition.

### TECHNICAL FIELD

The present invention relates to a method for producing an organic EL display device, and an organic EL display device.

### BACKGROUND ART

In recent years, self-luminous organic EL display devices including an organic electroluminescence (EL) element have received attention, as display devices alternative to liquid crystal display devices. Here, for such organic EL display devices, sealing techniques have been proposed for reducing the deterioration of an organic EL element caused by entry of moisture, oxygen, and other substances. Examples of such sealing techniques include a one drop fill (ODF) method in which a resin material is filled in a sealing material provided in a frame shape between substrates, and laser frit sealing in which a frit material made of glass and provided in a frame shape between substrates is melted and solidified by laser light.

For example, Patent Document 1 discloses an organic electric field light emission display device including not an organic planarization film provided under a glass frit but an interlayer insulating film comprised of an inorganic film, in order to prevent damage to the element due to high heat of laser light applied to the glass frit upon sealing the substrate.

### CITATION LIST

### Patent Documents

Patent Document 1: Japanese Unexamined Patent Publication No. 2007-200890

### SUMMARY OF THE INVENTION

### Technical Problem

In the ODF method and laser frit sealing described above, it is necessary to provide a sealing material and a frit material in a frame shape at the peripheral portion of the substrate. Thus, the frame area around the display area is widened. In addition, the organic EL display device might have the sealing performance deteriorated by pinholes and cracks formed in the inorganic film constituting the sealing film covering the organic EL element; interface peeling due to the film stress generated in the sealing film; and moisture intrusion from the entire end face of the sealing material.

In view of the foregoing, it is an object of the present invention to improve the sealing performance and achieve a narrower frame.

### Solution to the Problem

To achieve the object, the method for producing the organic EL display device according to the present invention includes an organic EL element formation step of forming an organic EL element on an base substrate; and a sealing film formation step of forming a sealing film covering the organic EL element. The sealing film formation step includes an atomic layer deposition step of forming an inorganic barrier film as the sealing film by atomic layer deposition and a molecular layer deposition step of forming an inorganic-organic composite barrier film as the sealing film by molecular layer deposition.

The organic EL display device according to the present invention includes a base substrate; an organic EL element provided on the base substrate; and a sealing film covering the organic EL element. The sealing film includes an inorganic barrier film and an inorganic-organic composite barrier film provided on the inorganic barrier film.

### Advantages of the Invention

According to the present invention, when a sealing film covering the organic EL element is formed, the inorganic barrier film is formed by the atomic layer deposition, and the inorganic-organic composite barrier film is formed by the molecular layer deposition. Thus, it is possible to improve the sealing performance and achieve a narrower frame.

### BRIEF DESCRIPTION OF THE DRAWINGS

FIG. 1 is a cross-sectional view showing a schematic configuration of an organic EL display device according to an first embodiment of the present invention.

FIG. 2 is a cross-sectional view showing an internal configuration of the organic EL display device according to the first embodiment of the present invention.

FIG. 3 is a cross-sectional view showing an organic EL layer constituting the organic EL display device according to the first embodiment of the present invention.

FIG. 4 is a view showing a method for producing the organic EL display device according to the first embodiment of the present invention.

FIG. 5 is a cross-sectional view showing a schematic configuration of an organic EL display device according to a second embodiment of the present invention.

FIG. 6 is a cross-sectional view showing a schematic configuration of an organic EL display device according to a third embodiment of the present invention.

### DESCRIPTION OF EMBODIMENTS

Embodiments of the present invention will be described in detail below, with reference to the drawings. Note that the present invention is not limited to the following embodiments.

### First Embodiment

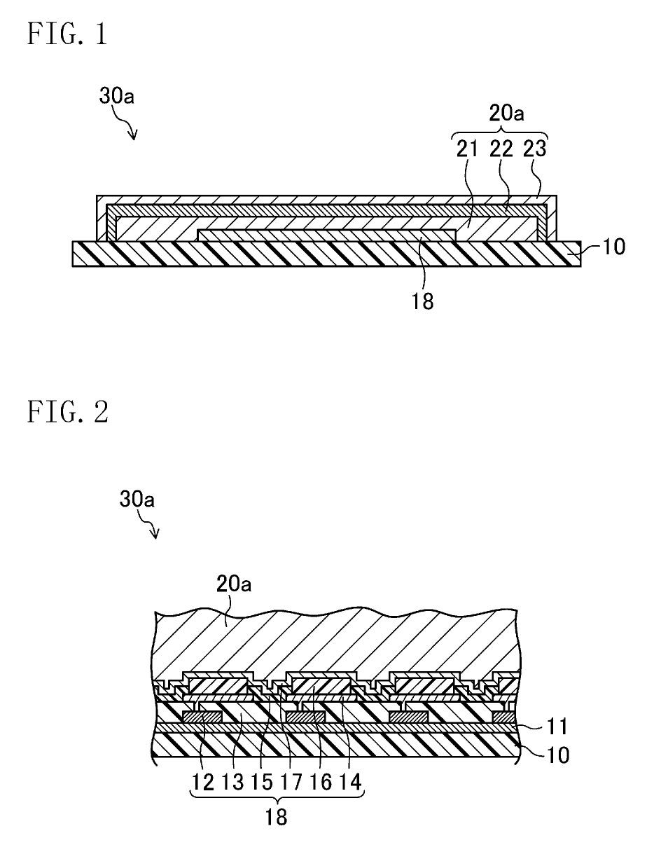

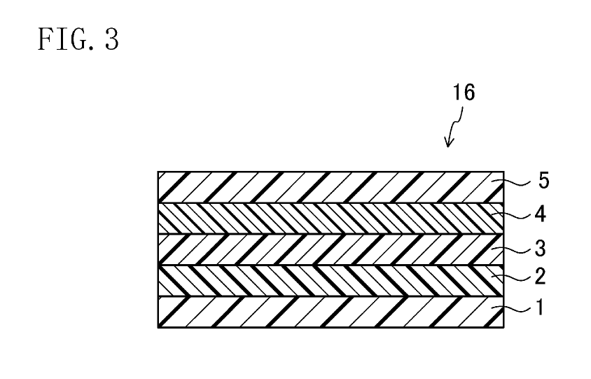

FIGS. 1 to 4 show an organic EL display device according to a first embodiment of the present invention. Here, FIG. 1 is a cross-sectional view showing a schematic configuration of the organic EL display device 30a of the present embodiment. FIG. 2 is a cross-sectional view showing an internal configuration for the organic EL display device 30a. FIG. 3 is a cross-sectional view of an organic EL layer 16 included in the organic EL display panel 30a.

As shown in FIGS. 1 and 2, the organic EL display device 30a includes: a base substrate 10; an organic EL element 18 provided over the base substrate 10 through a base coat film 11; and a sealing film 20a covering the organic EL element 18. Here, in the organic EL display device 30a, a display region to display images is provided in a rectangular shape, and multiple pixels are arranged in a matrix in the display region. For example, each pixel includes a set of sub-pixels arranged adjacent to each other. The set of sub-pixels includes a sub-pixel for gradation display in red, a sub-pixel for gradation display in green, and a sub-pixel for gradation display in blue. In the organic EL display device 30a, a frame region is provided in a frame shape around the rectangular display region.

The base substrate 10 is a plastic substrate made of, for example, polyimide resin, or a glass substrate.

The base coat film 11 is, for example, an inorganic insulating film such as a silicon dioxide film or a silicon nitride film.

As shown in FIG. 2, the organic EL element 18 includes a plurality of TFTs 12, an interlayer insulating film 13, a plurality of first electrodes 14, an edge cover 15, a plurality of organic EL layers 16, and a second electrode 17 which are sequentially provided over the base coat film 11.

As shown in FIG. 2, each of the TFTs 12 is a switching element provided on the base coat film 11 for an associated one of the sub-pixels. Here, each TFT 12 includes, for example: a gate electrode provided on the base coat film 11; a gate insulating film covering the gate electrode; a semiconductor layer provided over the gate insulating film and overlapping with the gate electrode; and source and drain electrodes provided over the semiconductor layer and facing each other. Note that each TFT 12 configured as a bottom gate TFT in this embodiment may be configured as a top gate TFT.

As shown in FIG. 2, the interlayer insulating film 13 covers each TFT 12, except for a portion of the drain electrode of the TFT 12. Here, the interlayer insulating film 13 is made of, for example, a transparent organic resin material such as acrylic resin.

As illustrated in FIG. 2, the plurality of first electrodes 14 are arranged in a matrix above the interlayer insulating film 13 such that each first electrode 14 corresponds to an associated one of the sub-pixels. Here, as illustrated in FIG. 2, the first electrodes 14 are connected to the respective drain electrodes of the TFTs 12 via contact holes formed in the interlayer insulating film 13. The first electrodes 14 have the function of injecting holes (positive holes) into the organic EL layers 16. To increase the efficiency in injecting positive holes into the organic EL layers 16, the first electrodes 14 are preferably made of a material having a high work function. Non-limiting examples of materials for the first electrodes 14 include metal materials such as silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The first electrodes 14 may also be made of an alloy of, for example, magnesium (Mg)/copper (Cu), magnesium (Mg)/silver (Ag), sodium (Na)/potassium (K), astatine (At)/astatine dioxide (AtO₂), lithium (Li)/aluminum (Al), lithium (Li)/calcium (Ca)/aluminum (Al), or lithium fluoride (LiF)/calcium (Ca)/aluminum (Al). Furthermore, the material for the first electrodes 14 may also be a conductive oxide such as tin oxide (SnO), zinc oxide (ZnO), indium tin oxide (ITO), and indium zinc oxide (IZO), for example. Moreover, the first electrodes 14 may be multilayers containing the above materials. Examples of materials having a high work function include indium tin oxide (ITO) and indium zinc oxide (IZO).

The edge cover 15 is formed in a grid pattern to cover a peripheral portion of each first electrode 14 as shown in FIG. 2. Non-limiting examples of materials for the edge cover 15 include an inorganic film of silicon dioxide (SiO₂), silicon nitride (SiNx, where x is a positive number) such as Si₃N₄, and silicon oxynitride (SiNO), or an organic film of polyimide resin, acrylic resin, polysiloxane resin, and novolak resin.

As shown in FIG. 2, the plurality of organic EL layers 16 are each provided on a respective one of the first electrodes 14, and are arranged in a matrix so as to correspond to the sub-pixels. Here, as shown in FIG. 3, each organic EL layer 16 includes a positive hole injection layer 1, a positive hole transport layer 2, a light-emitting layer 3, an electron transport layer 4, and an electron injection layer 5, which are provided over the associated first electrode 14 in this order.

The positive hole injection layer 1 is also called an anode buffer layer, and has a function of bringing the energy levels of the first electrodes 14 and the organic EL layers 16 closer to each other and increasing efficiency in injection of positive holes from the first electrodes 14 into the organic EL layers 16. Here, examples of materials for the positive hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The positive hole transport layer 2 has a function of increasing an efficiency in transportation of positive holes from the first electrodes 14 to the organic EL layers 16. Here, examples of materials for the positive hole transport layer 2 include porphyrin derivatives, aromatic tertiary amine compounds, styryl amine derivatives, polyvinylcarbazole, poly-p-phenylene vinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

When a voltage is applied from the first electrodes 14 and the second electrode 17, positive holes and electrons are injected from the first and second electrodes 14 and 17 into the light-emitting layer 3, in which the positive holes and the electrons are recombined with each other. The light-emitting layer 3 is made of a material having high luminous efficiency. Examples of materials for the light-emitting layer 3 include metal oxinoid compounds (8-hydroxyquinoline metal complexes), naphthalene derivatives, anthracene derivatives, diphenylethylene derivatives, vinylacetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bis(styryl)benzene derivatives, tris(styryl)benzene derivatives, perylene derivatives, perinone derivatives, aminopyrene derivatives, pyridine derivatives, rodamine derivatives, acridine derivatives, phenoxazone, quinacridone derivatives, rubrene, poly-p-phenylene vinylene, and polysilane.

The electron transport layer 4 functions to efficiently move electrons to the light-emitting layer 3. Here, examples of materials for the electron transport layer 4 includes, as organic compounds, oxadiazole derivatives, triazole derivatives, benzoquinone derivatives, naphthoquinone derivatives, anthraquinone derivatives, tetracyanoanthraquinodimethan derivatives, diphenoquinone derivatives, fluorenone derivatives, silole derivatives, and metal oxinoid compounds.

The electron injection layer 5 has a function of bringing the energy levels of the second electrode 17 and the organic EL layers 16 close to each other and increasing efficiency in injection of electron from the second electrode 17 into the organic EL layers 16. This function contributes to reduction in the drive voltage of the organic EL element 18. The electron injection layer 5 may also be called a cathode buffer layer. Here, examples of materials for the electron injection layer 5 include inorganic alkaline compounds such as lithium fluoride (LiF), magnesium fluoride (MgF₂), calcium fluoride (CaF₂), strontium fluoride (SrF₂), and barium fluoride (BaF₂), aluminum oxide (Al₂O₃), and strontium oxide (SrO).

As shown in FIG. 2, the second electrode 17 covers the organic EL layers 16 and the edge cover 15. The second electrode 17 has the function of injecting electrons into the organic EL layers 16. To increase efficiency in injecting electrons into the organic EL layers 16, the second electrode 17 is preferably made of a material having a low work function. Here, non-limiting examples of materials for the second electrode 17 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The second electrode 17 may also be made of, for example, an alloy of magnesium (Mg)/copper (Cu), magnesium (Mg)/silver (Ag), sodium (Na)/potassium (K), astatine (At)/astatine dioxide (AtO₂), lithium (Li)/aluminum (Al), lithium (Li)/calcium (Ca)/aluminum (Al), and lithium fluoride (LiF)/calcium (Ca)/aluminum (Al). The second electrode 17 may also contain, for example, a conductive oxide such as tin oxide (SnO), zinc oxide (ZnO), indium tin oxide (ITO), and indium zinc oxide (IZO). Moreover, the second electrode 17 may be multilayers containing the above materials. Examples of material having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

As shown in FIG. 1, the sealing film 20a includes an inorganic barrier film 21 provided to cover the organic EL element 18, an inorganic-organic composite barrier film 22 provided to cover the inorganic barrier film 21, and an inorganic barrier film 23 provided to cover the inorganic-organic composite barrier film 22. Here, the inorganic barrier films 21 and 23 are formed of, for example, an aluminum oxide film formed by atomic layer deposition (ALD). The inorganic-organic composite barrier film 22 is formed of, for example, an organic aluminum film (called alucone) formed by molecular layer deposition (MLD) and mixed and laminated with aluminum and ethylene glycol. Note that the atomic layer deposition is a film formation method where reaction products are deposited one by one at the atomic layer level by repeating the cycle of adsorbing and then reacting molecules (precursors) of the film formation material on the surface of the substrate placed in the vacuum chamber and removing excess molecules by purging with inert gas. The film formed by the atomic layer deposition is very thin, but is uniform and has high coverage. In addition, the molecular layer deposition is a film formation method derived from the atomic layer deposition, and is a film formation method where reaction products are deposited one by one at the molecular layer level.

The organic EL display device 30a having the configuration described above is flexible, and configured to display images by appropriately causing, via the TFTs 12, the light-emitting layers 3, which are included in the organic EL layers 16 and correspond to the respective sub-pixels, to emit light.

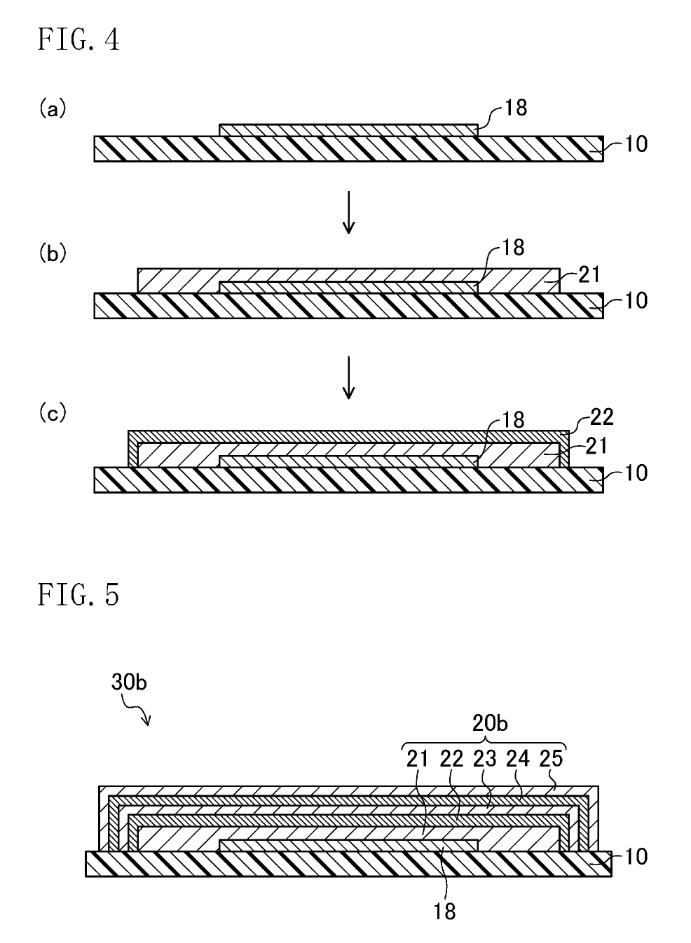

It is now described, with reference to FIG. 4, a method for producing the organic EL display device 30a of this embodiment. FIG. 4 is a view showing the method for producing the organic EL display device 30a. The method for producing the organic EL display device 30a according to this embodiment includes an organic EL element formation step, and a sealing film formation step including an atomic layer deposition step, a molecular layer deposition step, and another atomic layer deposition step.

### Organic EL Element Formation Step

For example, as shown in step (a) of FIG. 4, a well-known method is used to form the base coat film 11 (see FIG. 2) and the organic EL element 18 (the TFTs 12, the interlayer insulation film 13, the first electrodes 14, the edge cover 15, the organic EL layers 16 (each including the positive hole injection layer 1, the positive hole transport layer 2, the light-emitting layer 3, the electron transport layer 4, and the electron injection layer 5), and the second electrode 17) on the surface of the base substrate 10 made of polyimide resin.

### Sealing Film Formation Step

As shown in step (b) of FIG. 4, an aluminum oxide film with a film thickness of, e.g., about 10 nm or more and 500 nm or less is formed by the atomic layer deposition such that the inorganic barrier film 21 is formed to cover the organic EL element 18 formed in the organic EL element formation step (the atomic layer deposition step). Here, if the aluminum oxide film has a film thickness smaller than 10 nm, the inorganic barrier film 21 might have the barrier performance deteriorated. If the aluminum oxide film has a film thickness larger than 500 nm, the inorganic barrier film 21 might be cracked due to the film stress.

As shown in step (c) of FIG. 4, an organic aluminum film with a film thickness of, e.g., about 10 nm or more and 1000 nm or less is formed by the molecular layer deposition where trimethylaluminum and ethylene glycol are excited by the high frequency power of, e.g., 13.56 MHz and reacted in a plasma state, such that the inorganic-organic composite barrier film 22 is formed to cover the inorganic barrier film 21 (the molecular layer deposition step). Here, if the organic aluminum film has a film thickness smaller than 10 nm, the inorganic-organic composite barrier film 22 might have the barrier performance deteriorated. If the organic aluminum film has a film thickness larger than 1000 nm, the inorganic-organic composite barrier film 22 might be cracked due to the film stress.

As shown in FIG. 1, an aluminum oxide film with a film thickness of, e.g., about 10 nm or more and 500 nm or less is formed by the atomic layer deposition such that the inorganic barrier film 23 is formed to cover the inorganic-organic composite barrier film 22 (the atomic layer deposition step). Here, if the aluminum oxide film has a film thickness smaller than 10 nm, the inorganic barrier film 23 might have the barrier performance deteriorated. If the aluminum oxide film has a film thickness larger than 500 nm, the inorganic barrier film 23 might be cracked due to the film stress.

In this embodiment, the sealing film 20a having the three-layer laminated structure including the inorganic barrier film 21, the inorganic-organic composite barrier film 22, and the inorganic barrier film 23 is exemplified, whereas the sealing film 20a may have the two-layer laminated structure including the inorganic barrier film 21 and the inorganic-organic composite barrier film 22.

In the above manner, the organic EL display device 30a of this embodiment can be produced.

As can be seen, the organic EL display device 30a and the method for producing the same of this embodiment can provide the following advantages (1) and (2).

(1) The sealing film formation step of forming the sealing film 20a includes the atomic layer deposition steps and the molecular layer deposition step. In the atomic layer deposition steps performed as the first and third steps, an aluminum oxide film is formed by the atomic layer deposition to form the inorganic barrier films 21 and 23. In the molecular layer deposition step performed as the second step, an organic aluminum film is formed by the molecular layer deposition to form the inorganic-organic composite barrier film 22. Here, in the atomic layer deposition step as the first step, the inorganic barrier film 21 made of the aluminum oxide film is formed by the atomic layer deposition to cover the organic EL element 18. Thus, even if pinholes or cracks are formed on the surface of the organic EL element 18, i.e., on the surface of the second electrode 17, the inorganic barrier film 21 can be formed also in the pinholes or the cracks. In the molecular layer deposition step as the second step, the inorganic-organic composite barrier film 22 made of the organic aluminum film is formed by the molecular layer deposition to cover the inorganic barrier film 21. Thus, the film stress generated in the sealing film 20a can be reduced. Moreover, in the atomic layer deposition step as the third step, the inorganic barrier film 23 made of the aluminum oxide film is formed by the atomic layer deposition to cover the inorganic-organic composite barrier film 22. Thus, even if pinholes or cracks are formed on the surface of the inorganic-organic composite barrier film 22, the inorganic barrier film 23 can be formed also in the pinholes or the cracks. Thus, the three-layer laminated films including the inorganic barrier film 21, the inorganic-organic composite barrier film 22, and the inorganic barrier film 23 can provide the sealing film 20a that is closely packed and has few pinholes and cracks. Thus, the sealing performance of the organic EL display device 30a can be improved. Moreover, due of the improved sealing performance of the organic EL display device 30a by the sealing film 20a, it is unnecessary to use a frame-shaped sealing material and frit material at the peripheral edge of the substrate, which has been required for typical sealing techniques such as the ODF method and the laser frit sealing. Thus, the frame area around the display area can be narrowed. This can provide the improved sealing performance of the organic EL display device 30b, and a narrower frame can be achieved.

(2) Due to the improved sealing performance of the organic EL display device 30a by the sealing film 20a, it is unnecessary to affix a sealing facing substrate facing the base substrate 10. Thus, the product cost and manufacturing cost can be reduced.

### Second Embodiment

FIG. 5 shows an organic EL display device according to a second embodiment of the present invention. Here, FIG. 5 is a cross-sectional view showing a schematic configuration of an organic EL display device 30b of the present embodiment. In the embodiments below, components equivalent to those shown in FIGS. 1 to 4 are denoted by the same reference characters, and the detailed explanation thereof will be omitted.

In the first embodiment, the organic EL display device 30a including the sealing film 20a having the three-layer laminated structure is exemplified, whereas in this embodiment, the organic EL display device 30b including a sealing film 20b having a five-layer laminated structure is exemplified.

As shown in FIG. 5, the organic EL display device 30b includes: a base substrate 10; an organic EL element 18 provided over the base substrate 10 through a base coat film 11 (see FIG. 2); and a sealing film 20b covering the organic EL element 18. Here, in the organic EL display device 30b, a display region to display images is provided in a rectangular shape, and multiple pixels are arranged in a matrix in the display region.

As shown in FIG. 5, the sealing film 20b includes an inorganic barrier film 21 provided to cover the organic EL element 18, an inorganic-organic composite barrier film 22 provided to cover the inorganic barrier film 21, an inorganic barrier film 23 provided to cover the inorganic-organic composite barrier film 22, an inorganic-organic composite barrier film 24 provided to cover the inorganic barrier film 23, and an inorganic barrier film 25 provided to cover the inorganic-organic composite barrier film 24. Here, the inorganic barrier layer 25 is substantially the same as the inorganic barrier films 21 and 23 of the first embodiment. The inorganic-organic composite barrier film 24 is substantially the same as the inorganic-organic composite barrier film 22 of the first embodiment.

In this embodiment, the organic EL display device 30b including the sealing film 20b having the five-layer laminated structure is exemplified, whereas the sealing film 20b may have a four-layer laminated structure or a laminated structure having six or more layers where at least the outermost layer is an inorganic barrier film.

The organic EL display device 30b having the configuration described above is flexible, and configured to display images by appropriately causing, via the TFTs 12, the light-emitting layers 3, which are included in the organic EL layers 16 and correspond to the respective sub-pixels, to emit light.

The organic EL display device 30b of this embodiment can be produced by, after the atomic layer deposition step as the third step in the sealing film formation step of the first embodiment, performing the molecular layer deposition step as the fourth step similar to the second step, and then performing the atomic layer deposition step as the fifth step similar to the first and third steps.

As can be seen, the organic EL display device 30b and the method for producing the same of this embodiment can provide the above-described advantages (1) and (2) and the advantage (3) described below.

The advantage (1) will be described in detail. The sealing film formation step of forming the sealing film 20b includes the atomic layer deposition steps and the molecular layer deposition steps. In the atomic layer deposition steps performed as the first, third, and fifth steps, an aluminum oxide film is formed by the atomic layer deposition to form the inorganic barrier films 21, 23, and 25. In the molecular layer deposition step performed as the second and fourth steps, an organic aluminum film is formed by the molecular layer deposition to form the inorganic-organic composite barrier films 22 and 24. Here, in the atomic layer deposition step as the first step, the inorganic barrier film 21 made of the aluminum oxide film is formed by the atomic layer deposition to cover the organic EL element 18. Thus, even if pinholes or cracks are formed on the surface of the organic EL element 18, i.e., on the surface of the second electrode 17, the inorganic barrier film 21 can be formed also in the pinholes or the cracks. In the molecular layer deposition step as the second step, the inorganic-organic composite barrier film 22 made of the organic aluminum film is formed by the molecular layer deposition to cover the inorganic barrier film 21. Thus, the film stress generated in the sealing film 20b can be reduced. In the atomic layer deposition step as the third step, the inorganic barrier film 23 made of the aluminum oxide film is formed by the atomic layer deposition to cover the inorganic-organic composite barrier film 22. Thus, even if pinholes or cracks are formed on the surface of the inorganic-organic composite barrier film 22, the inorganic barrier film 23 can be formed also in the pinholes or the cracks. In the molecular layer deposition step as the fourth step, the inorganic-organic composite barrier film 24 made of the organic aluminum film is formed by the molecular layer deposition to cover the inorganic barrier film 23. Thus, the film stress generated in the sealing film 20b can be reduced. Moreover, in the atomic layer deposition step as the fifth step, the inorganic barrier film 25 made of the aluminum oxide film is formed by the atomic layer deposition to cover the inorganic-organic composite barrier film 24. Thus, even if pinholes or cracks are formed on the surface of the inorganic-organic composite barrier film 24, the inorganic barrier film 25 can be formed also in the pinholes or the cracks. Thus, the five-layer laminated films including the inorganic barrier film 21, the inorganic-organic composite barrier film 22, the inorganic barrier film 23, the inorganic-organic composite barrier film 24, and the inorganic barrier film 25 can provide the sealing film 20b that is closely packed and has few pinholes and cracks. Thus, the sealing performance of the organic EL display device 30b can be improved. Moreover, due to the improved sealing performance of the organic EL display device 30b by the sealing film 20b, it is unnecessary to use a frame-shaped sealing material and frit material at the peripheral edge of the substrate, which has been required for typical sealing techniques such as the ODF method and the laser frit sealing. Thus, the frame area around the display area can be narrowed. This can provide the improved sealing performance of the organic EL display device 30b, and a narrower frame can be achieved.

(3) The sealing film 20b has the a five-layer laminated structure, and thus can provide a more improved sealing performance than that of the organic EL display device 30a of the first embodiment including the sealing film 20a having the three-layer laminated structure.

### Third Embodiment

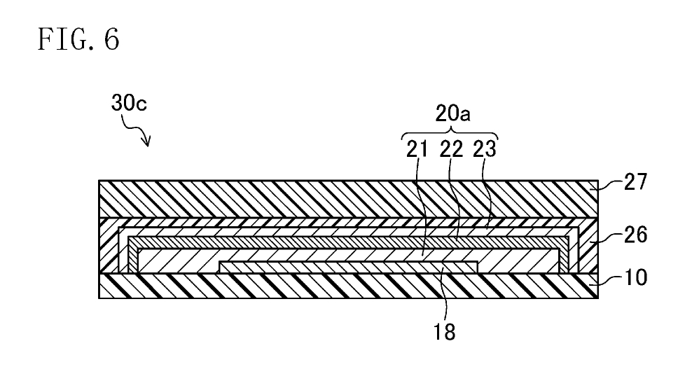

FIG. 6 shows an organic EL display device according to a third embodiment of the present invention. Here, FIG. 6 is a cross-sectional view showing a schematic configuration of the organic EL display device 30c of the present embodiment.

In the first embodiment, the organic EL display devices 30a and 30b including no cover base member (a facing substrate) has been exemplified. In this embodiment, the organic EL display device 30c including a cover base member 27 is exemplified.

As shown in FIG. 6, the organic EL display device 30a includes: a base substrate 10; an organic EL element 18 provided over the base substrate 10 through a base coat film 11; a sealing film 20a covering the organic EL element 18; and a cover base member 27 provided over the sealing film 20a through an adhesive layer 26. Here, in the organic EL display device 30c, a display region to display images is provided in a rectangular shape, and multiple pixels are arranged in a matrix in the display region.

The adhesive layer 26 is formed from, e.g., epoxy resin, acrylic resin, polyimide resin, and phenol resin which are UV curable and/or thermosetting.

The cover base member 27 is a plastic substrate made of, for example, polyimide resin, or a glass substrate.

The organic EL display device 30c having the configuration described above is flexible, and configured to display images by appropriately causing, via the TFTs 12, the light-emitting layers 3, which are included in the organic EL layers 16 and correspond to the respective sub-pixels, to emit light.

The organic EL display device 30c of this embodiment can be produced by, after the sealing film formation step of the first embodiment, first, applying and forming an adhesive layer 26 on the sealing film 20a, then, affixing the cover base member 27 in a dry atmosphere or a reduced pressure atmosphere, and also performing an affixing step of hardening the adhesive layer 26.

As can be seen, the organic EL display device 30c and the method for producing the same of this embodiment can provide the above-described advantage (1) and the advantage (4) described below.

(4) The organic EL display device 30c includes the cover base member 27. The surface tolerance of the organic EL display device 30c can be improved.

### Other Embodiments

In the above embodiments, the organic EL display devices 30a to 30c have been exemplified. Alternatively, the present invention is applicable to an organic EL display device including any combination of two or more of the stacks of the exemplified organic EL display devices 30a to 30c.

Moreover, in each of the above embodiments, the organic EL layer has been exemplified as a layer having a stacked structure of the five layers, namely, the positive hole injection layer, a positive hole transport layer, the light-emitting layer, the electron transport layer, and the electron injection layer. Alternatively, the organic EL layer may have a stacked structure of three layers including a positive hole injection and transport layer, a light-emitting layer, and an electron transport and injection layer, for example.

In each of the above embodiments, the organic EL display device in which the first electrode functions as the anode and the second electrode functions as the cathode has been exemplified. Alternatively, the present invention is applicable to an organic EL display device in which the stacked structure of the organic EL element is inverted, the first electrode functions as the cathode, and the second electrode functions as the anode.

In each of the above embodiments, the organic EL display device including the element substrate in which an electrode of the TFT connected to the first electrode is denoted as the drain electrode has been exemplified. Alternatively, the present invention is applicable to an organic EL display device including an element substrate in which the electrode of the TFT connected to the first electrode is called a source electrode.

### INDUSTRIAL APPLICABILITY

As can be seen from the foregoing description, the present invention is useful for a flexible organic EL display device.

### DESCRIPTION OF REFERENCE CHARACTERS

10 Base Substrate
18 Organic EL Element
20a, 20b Sealing Film
21, 23, 25 Inorganic Barrier Film
22, 24 Inorganic-Organic Composite Barrier Film
27 Cover Base Member
30a to 30c Organic EL Display Device

1. A method for producing an organic EL display device, the method comprising:
an organic EL element formation step of forming an organic EL element on an base substrate; and
a sealing film formation step of forming a sealing film covering the organic EL element,
wherein
the sealing film formation step includes
an atomic layer deposition step of forming an inorganic barrier film as the sealing film by atomic layer deposition and
a molecular layer deposition step of forming an inorganic-organic composite barrier film as the sealing film by molecular layer deposition.

2. The method of claim 1, wherein
in the sealing film formation step, the atomic layer deposition step and the molecular layer deposition step are alternately repeated, and the atomic layer deposition step is performed a plurality of times.

3. The method of claim 1, wherein
the inorganic barrier film is an aluminum oxide film having a thickness of 10 nm or more and 500 nm or less, and
the inorganic-organic composite barrier film is an organic aluminum film having a thickness of 10 nm or more and 1000 nm or less.

4. The method of claim 3, wherein
the organic aluminum film is formed by reacting trimethylaluminum and ethylene glycol in a plasma state.

5. The method of claim 1, further comprising:
an affixing step of affixing a cover base member facing the base substrate on the sealing film.

6. An organic EL display device, comprising:
a base substrate;
an organic EL element provided on the base substrate; and
a sealing film covering the organic EL element,
wherein
the sealing film includes an inorganic barrier film and an inorganic-organic composite barrier film provided on the inorganic barrier film.

7. The organic EL display device of claim 6, wherein
the inorganic barrier film is an aluminum oxide film having a thickness of 10 nm or more and 500 nm or less, and
the inorganic-organic composite barrier film is an organic aluminum film having a thickness of 10 nm or more and 1000 nm or less.

8. The organic EL display device of claim 7, wherein
the organic aluminum film is formed by mixing and laminating aluminum and ethylene glycol.

9. The organic EL display device of claim 6, wherein
a cover base member facing the base substrate is provided on the sealing film.
